(19) United States
(12) Patent Application Publication
(10) Pub. No.: US 2023/0280913 A1
(43) Pub. Date: Sep. 7, 2023

(54) ELECTRONIC DEVICE USING EXTERNAL MEMORY DEVICE TO STORE HARDWARE SETTING OF SEMICONDUCTOR CHIP FOR FAST BOOT AND POWER SAVING OF SEMICONDUCTOR CHIP

(71) Applicant: MEDIATEK INC., Hsin-Chu (TW)

(72) Inventors: Yu-Hua Huang, Hsinchu City (TW); Po-Chao Fang, Hsinchu City (TW); Wei-Yu Ma, Hsinchu City (TW); Chung-Hsin Huang, Hsinchu City (TW)

(73) Assignee: MEDIATEK INC., Hsin-Chu (TW)

(21) Appl. No.: 18/078,047

(22) Filed: Dec. 8, 2022

Related U.S. Application Data
(60) Provisional application No. 63/315,591, filed on Mar. 2, 2022.

(51) Int. Cl. G06F 3/06; G11C 11/406; G11C 11/4074; G11C 11/4093

(52) U.S. Cl. CPC G06F 3/0625; G11C 11/40615; G11C 11/4074; G11C 11/4093; G06F 3/0611; G06F 3/0673; G06F 3/0659

(57) ABSTRACT

An electronic device includes a semiconductor chip and a first memory device. The semiconductor chip includes an input/output (I/O) interface circuit. The first memory device is external to the semiconductor chip. The semiconductor chip communicates with the first memory device via the I/O interface circuit. The semiconductor chip stores at least one hardware setting of the semiconductor chip into the first memory device before a power-off event of the semiconductor chip.

### CROSS REFERENCE TO RELATED APPLICATIONS

This application claims the benefit of U.S. Provisional Application No. 63/315,591, filed on Mar. 2, 2022. The content of the application is incorporated herein by reference.

### BACKGROUND

The present invention relates to an integrated circuit design, and more particularly, to an electronic device using an external memory device to store hardware setting(s) of a semiconductor chip for fast boot and power saving of the semiconductor chip.

A system on a chip (SoC) is essentially an integrated circuit that takes a single platform and integrates a plurality of processing devices onto it. For example, the processing devices integrated within the same chip may include a processor, an input/output interface, an internal memory, etc. Depending on the kind of system that has been reduced to the size of a single chip, it can perform a variety of functions including signal processing, wireless communication, etc. The SoC may leave a normal mode and enter a power saving mode for power consumption reduction. However, due to low latency requirements of restoring the normal mode from the power saving mode, the conventional SoC may have certain components that need to be powered on all the time, which results in extra power cost inevitably.

Thus, there is a need for an innovative SoC design that is capable of meeting the low latency requirements as well as the low power requirements.

### SUMMARY

One of the objectives of the claimed invention is to provide an electronic device using an external memory device to store hardware setting(s) of a semiconductor chip for fast boot and power saving of the semiconductor chip.

According to a first aspect of the present invention, an exemplary electronic device is disclosed. The exemplary electronic device includes a semiconductor chip and a first memory device. The semiconductor chip includes an input/output (I/O) interface circuit. The first memory device is external to the semiconductor chip. The semiconductor chip communicates with the first memory device via the I/O interface circuit. The semiconductor chip is arranged to store at least one hardware setting of the semiconductor chip into the first memory device before a power-off event of the semiconductor chip.

According to a second aspect of the present invention, an exemplary electronic device is disclosed. The exemplary electronic device includes a semiconductor chip and a first memory device. The semiconductor chip includes an input/output (I/O) interface circuit. The first memory device is external to the semiconductor chip. The semiconductor chip communicates with the first memory device via the I/O interface circuit. The semiconductor chip is arranged to fetch at least one hardware setting of the semiconductor chip from the first memory device after a power-on event of the semiconductor chip.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating an electronic device according to an embodiment of the present invention.

FIG. 2 is a sequence diagram illustrating interactions between circuit components for making a semiconductor chip in FIG. 1 enter the proposed fast boot mode for power saving.

FIG. 3 is a sequence diagram illustrating interactions between circuit components for making the semiconductor chip in FIG. 1 leave the proposed fast boot mode for fast boot.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

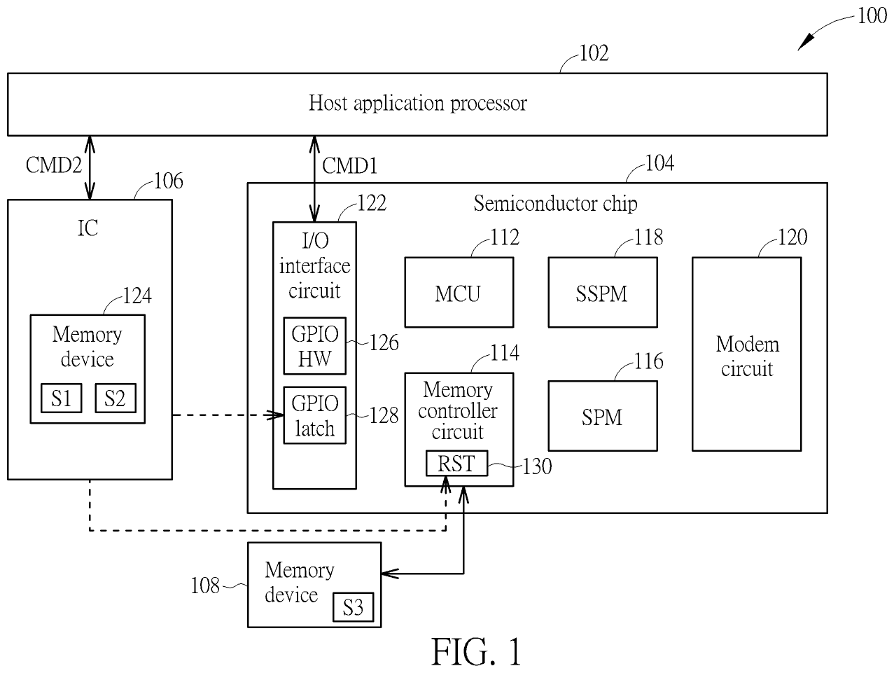

FIG. 1 is a block diagram illustrating an electronic device according to an embodiment of the present invention. Byway of example, but not limitation, the electronic device 100 may be a portable device powered by a battery device, such as a smartphone. The electronic device 100 may include a host application processor 102, a semiconductor chip 104, an integrated circuit (IC) 106, and a memory device 108. For example, the semiconductor chip 104 may be a radio-frequency (RF) SoC, the IC 106 may be a microprocessor, a power management integrated circuit (PMIC), or any control circuit that is external to the semiconductor chip 104 and can cooperate with the semiconductor chip 104 to achieve fast boot and power saving of the semiconductor chip 104, and the memory device 108 may be a dynamic random access memory (DRAM), such as a low power double data rate synchronous dynamic random access memory (LPDDR SDRAM). Regarding the semiconductor chip 104, it may have a plurality of circuits, including a microcontroller unit (MCU) 112, a memory controller circuit (e.g., DRAM controller) 114, a system power manager (SPM) 116, a secure system power manager (SSPM) 118, a modulator/demodulator (modem) circuit 120, and an input/output (I/O) interface circuit 122. Regarding the IC (e.g., PMIC) 106 that is external to the semiconductor chip (e.g., RF SoC) 104, it may include a memory device 124. Specifically, the memory device 124 is an internal memory of the IC 106. For example, the memory device 124 may be a static random access memory (SRAM).

Each of the host application processor 102, the IC 106 and the memory device 108 may communicate with the semiconductor chip 104 via the I/O interface circuit 122. For example, the I/O interface circuit 122 may be a high-speed I/O interface with a plurality of I/O pins, where some of the I/O pins may be general-purpose input/output (GPIO) pins. In this embodiment, the I/O interface circuit 122 may include GPIO hardware (labeled by “GPIO HW”) 126 and a GPIO latch circuit (labeled by “GPIO latch”) 128, where the GPIO latch circuit 128 is arranged to latch status of the GPIO hardware 126. In a case where the off-chip memory device 108 accessible to the semiconductor chip 104 is a DRAM, one I/O pin of the semiconductor chip 104 may be a DRAM reset (labeled by “RST”) pin 130 that can be driven by the memory controller circuit 114 (which is a memory controller of the off-chip memory device 108), where the DRAM reset pin 130 can be used to control isolation of the off-chip memory device 108.

The semiconductor chip 104 is arranged to store at least one hardware setting of the semiconductor chip 104 into the memory device 124 of the IC 106 before a power-off event of the semiconductor chip 104. That is, backup(s) of hardware setting(s) of the semiconductor chip 104 are stored into the memory device 124 of the IC 106 before the semiconductor chip 104 is powered off for power saving. Furthermore, the semiconductor chip 104 is arranged to fetch at least one hardware setting of the semiconductor chip 104 from the memory device 124 after a power-on event of the semiconductor chip 104. That is, after the semiconductor chip 104 is powered on, the semiconductor chip 104 loads backup(s) of hardware setting(s) of the semiconductor chip 104 from the memory device 124 of the IC 106 for fast boot. In some embodiments of the present invention, hardware setting(s) of the semiconductor chip 104 that are backed up in the memory device 124 of the IC 106 may include memory parameters (e.g., DRAM parameters) S1 of the memory device 108 and/or GPIO pinmux parameters S2 of the I/O interface circuit 122. To put it simply, the present invention proposes a fast boot mode for the semiconductor chip 104 that is capable of meeting the low latency requirements and low power requirements. The fast boot mode may be regarded as an advanced power saving mode that supports fast boot functionality. Hence, when the fast boot mode is activated, the semiconductor chip 104 enters a power saving mode, and has fast boot information backed up in an external memory device; and when the fast boot mode is deactivated, the semiconductor chip 104 leaves the power saving mode, and has shorter boot time by using the fast boot information fetched from the external memory device. Further details of the proposed fast boot mode of the semiconductor chip 104 are described with referenced to the accompanying drawings.

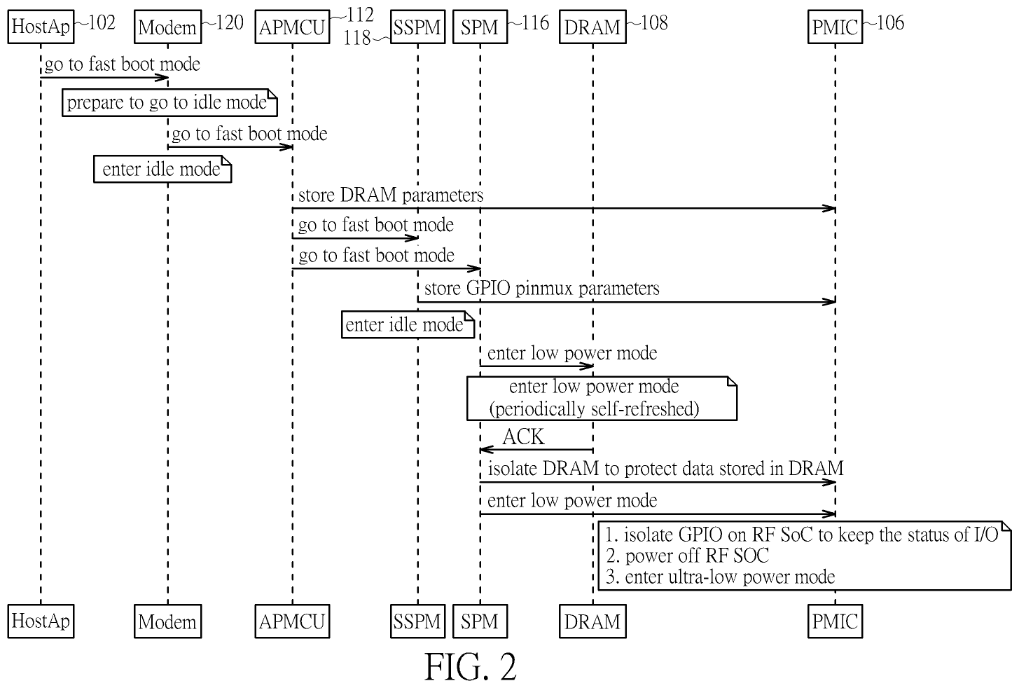

Please refer to FIG. 1 in conjunction with FIG. 2. FIG. 2 is a sequence diagram illustrating interactions between circuit components for making the semiconductor chip 104 enter the proposed fast boot mode for power saving. For better comprehension of the technical features, the following assumes that the semiconductor chip 104 is an RF SoC, the IC 106 is a PMIC, the memory device 124 is an SRAM, the memory device 108 is a DRAM, the memory controller circuit 124 is a DRAM controller, and the MCU 112 is an application processor MCU (APMCU). Hence, the terms “semiconductor chip 104” and “RF SoC 104” may be interchangeable, the terms “IC 106” and “PMIC 106” may be interchangeable, the terms “memory device 124” and “SRAM 124” may be interchangeable, the terms “memory controller circuit 124” and “DRAM controller 124” may be interchangeable, the terms “memory device 108” and “DRAM 108” may be interchangeable, and the terms “MCU 112” and “APMCU 112” may be interchangeable.

The host application processor (labeled by “HostAP” in FIG. 2) 102 sends a command CMD1 to the RF SoC 104 (particularly, modem circuit 120 of SoC 104) for activation of a fast boot mode (i.e., mode switching from the normal mode to the fast boot mode). After receiving the command CMD1, the modem circuit 120 prepares to go to an idle mode. Before entering the idle mode, the modem circuit 120 instructs the APMCU 112 to go to the fast boot mode.

In response to the instruction from the modem circuit 120, the APMCU 112 stores a backup of memory parameters (DRAM parameters) S1 of the DRAM 108 into the PMIC 106 (particularly, SRAM 124 of PMIC 106), where the memory parameters (DRAM parameters) S1 are referenced by the DRAM controller 114 for controlling access of the DRAM 108. In addition, the APMCU 112 instructs SSPM 118 and SPM 116 to go to the fast boot mode.

In response to the instruction from the APMCU 112, the SSPM 118 stores a backup of GPIO pinmux parameters S2 that are used to configure the GPIO hardware 126 of the I/O interface 122 into the PMIC 106 (particularly, SRAM 124 of PMIC 106), and then enters an idle mode.

In response to the instruction from the APMCU 112, the SPM 116 sends a command to the DRAM controller 114, such that the DRAM controller 114 instructs the DRAM 108 to leave a normal mode and enter a self-refresh mode (which is a low power mode due to the fact that the DRAM 108 is periodically self-refreshed). After receiving an acknowledgement (ACK) from the DRAM 108 that enters the self-refresh mode, the SPM 116 instructs the PMIC 106 to isolate the DRAM 108 for protecting data stored in the DRAM 108. For example, the PMIC 106 asserts the DRAM controller 114 of the RF SoC 104 to make the DRAM 108 enter an isolation state. When the DRAM 108 is isolated, the data stored in the DRAM 108 is blocked from being modified. Next, the SPM 116 instructs the PMIC 106 to enter a low power mode.

In response to the instruction from the SPM 116, the PMIC 106 enables the GPIO latch circuit 128 to keep status of the GPIO hardware 126, and makes the GPIO hardware 126 enter an isolation state for protecting the GPIO hardware 126 from unexpected exception caused by external signals and/or for keeping GPIO hardware 126 status to protect the companion chip from receiving unexpected/unknown output values from GPIO hardware 126 of RF SoC 104. For example, the GPIO hardware 126 may output a high state (e.g. VDD) to make unexpected interrupt to the companion host application processor 102. With the help of the isolation, the GPIO hardware 126 is not accessed unexpectedly, thereby preventing unexpected unknown signal from power-off domain causing GPIO leakage. With the help of the GPIO latch circuit 128, the status of GPIO hardware 126 is not floating.

Next, the PMIC 106 triggers a power-off event of the RF SoC 104 for powering off all on-chip circuits of the RF SoC 104 except GPIO external pins, and then enters an ultra-low power mode. It should be noted that the SRAM 124 and the DRAM 108 are still powered by the PMIC 106 when the PMIC 106 operates in the ultra-low power mode. Since both of the RF SoC 104 and the PMIC 106 operate in the low power mode, the overall power consumption of the electronic device 100 can be greatly reduced after activation of the fast boot mode.

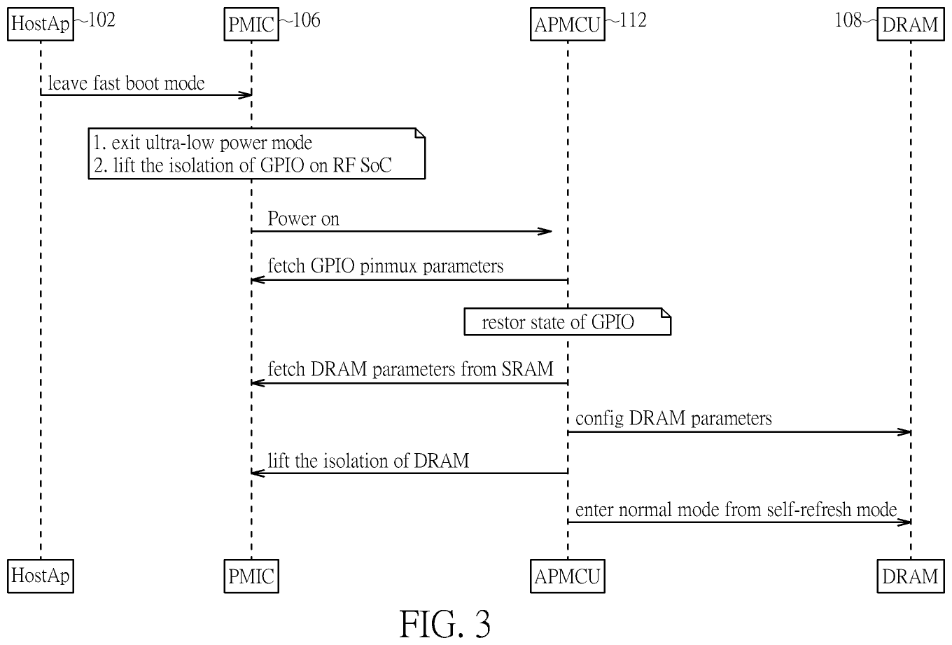

Please refer to FIG. 1 in conjunction with FIG. 3. FIG. 3 is a sequence diagram illustrating interactions between circuit components for making the semiconductor chip 104 leave the proposed fast boot mode for fast boot. The host application processor (labeled by “HostAP” in FIG. 3) 102 sends a command CMD2 to the PMIC 106 for deactivation of the fast boot mode (i.e., mode switching from the fast boot mode to the normal mode). After receiving the command CMD2, the PMIC 106 exits the ultra-low power mode, makes the GPIO hardware 126 leave the isolation state, and disables the GPIO latch circuit 128. At this moment, the protection of the GPIO hardware 126 is released.

Next, the PMIC 106 triggers a power-on event of the RF SoC 104 for powering on on-chip circuits of the RF SoC 104, such that a boot sequence of the RF SoC 104 is started. The APMCU 112 fetches GPIO pinmux parameters S2 from the PMIC 106 (particularly, SRAM 124 of PMIC 106), and refers to the fetched GPIO pinmux parameters to quickly restore state of the GPIO hardware 126. In addition, the APMCU 112 fetches memory parameters (DRAM parameters) S1 from the PMIC 106 (particularly, SRAM 124 of PMIC 106), and refers to the fetched DRAM parameters S1 to quickly configure the DRAM controller 114. Since the hardware status of the GPIO hardware 126 and the DRAM controller 114 can be restored without extra hardware initialization, the RF SoC 104 can speed up the boot sequence and thus have shorter boot time.

In addition, the APMCU 112 instructs the PMIC 106 to make the DRAM 108 leave the isolation state. For example, the PMIC 106 deasserts the DRAM reset pin 130 of the RF SoC 104 to release protection of the DRAM 108. Furthermore, the APMCU 112 sends a command to the DRAM controller 114, such that the DRAM controller 114 instructs the DRAM 108 to leave the self-refresh mode and re-enter the normal mode.

As mentioned above, after the host application processor 102 activates the fast boot mode (which is an advanced power-saving mode that supports fast boot functionality), the DRAM 108 is instructed to enter the self-refresh mode for power saving and is isolated to protect the stored data from being modified. In some embodiments of the present invention, the DRAM 108 may be used to store a hardware setting S3 of the modem circuit 120 before entering the self-refresh mode. Hence, before the power-off event of the RF SoC 104, the RF SoC 104 has the hardware setting S3 of the modem circuit 120 that is backed up in the DRAM 108 via the DRAM controller 114. After the host application processor 102 deactivates the fast boot mode (which is an advanced power-saving mode that supports fast boot functionality), parameters of the DRAM 108 are loaded from the SRAM 124 of the PMIC 106 to restore status of the DRAM controller 114, which enables the DRAM controller 114 to normally access the DRAM 108 after the power-on event of the RF SoC 104. At this moment, the RF SoC 104 can load the hardware setting S3 of the modem circuit 120 from the DRAM 108 via the DRAM controller 114 to quickly restore state of the modem circuit 120, which can reduce the network camping time between RF SoC 104 and an operator core network (not shown).

It should be noted that there is no special hardware restore engine implemented in the semiconductor chip (e.g., RF SoC) 104 for dealing with power-saving related operations. Compared to a semiconductor chip having a special hardware restore engine implemented therein for dealing with power-saving related operations, the semiconductor chip (e.g., RF SoC) 104 can have lower power consumption after entering a power-saving mode, thus meeting the low power requirements. Furthermore, the semiconductor chip (e.g., RF SoC) 104 backs up its hardware setting(s) in the memory device 124. Hence, the semiconductor chip (e.g., RF SoC) 104 can fetch the hardware setting(s) from the memory device 124/108 to speed up the boot sequence/network camping, thus meeting the low latency requirements.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device comprising:
a semiconductor chip, comprising an input/output (I/O) interface circuit; and
a first memory device, external to the semiconductor chip;
wherein the semiconductor chip communicates with the first memory device via the I/O interface circuit; and the semiconductor chip is arranged to store at least one hardware setting of the semiconductor chip into the first memory device before a power-off event of the semiconductor chip.

2. The electronic device of claim 1, wherein the first memory device is an internal memory of an integrated circuit (IC) of the electronic device.

3. The electronic device of claim 2, wherein the IC is arranged to enter a power saving mode after the power-off event of the semiconductor chip.

4. The electronic device of claim 2, wherein the I/O interface circuit comprises:
general-purpose input/output (GPIO) hardware; and
a GPIO latch circuit, arranged to latch status of the GPIO hardware;
the IC is arranged to enable the GPIO latch circuit before the power-off event of the semiconductor chip.

5. The electronic device of claim 2, wherein the I/O interface circuit comprises general-purpose input/output (GPIO) hardware; and the IC is arranged to make the GPIO hardware enter an isolation state before the power-off event of the semiconductor chip, to prevent unexpected unknown signal from a power-off domain causing GPIO leakage.

6. The electronic device of claim 1, further comprising:
a second memory device, external to the semiconductor chip;
wherein the semiconductor chip further comprises:
a memory controller circuit, arranged to control access of the second memory device, wherein the memory controller circuit is further arranged to instruct the second memory device to enter a self-refresh mode before the power-off event of the semiconductor chip.

7. The electronic device of claim 1, further comprising:
a second memory device, external to the semiconductor chip;
wherein the semiconductor chip further comprises:
a memory controller circuit, arranged to control access of the second memory device; and
the IC is further arranged to make the second memory device enter an isolation state before the power-off event of the semiconductor chip.

8. The electronic device of claim 1, further comprising:
a second memory device, external to the semiconductor chip;
wherein the semiconductor chip further comprises:
a memory controller circuit, arranged to control access of the second memory device according to memory parameters of the second memory device, where said at least one hardware setting comprises the memory parameters of the second memory device.

9. The electronic device of claim 1, wherein said at least one hardware setting comprises general-purpose input/output (GPIO) pinmux parameters of the I/O interface circuit.

10. The electronic device of claim 1, further comprising:
a second memory device, external to the semiconductor chip;
wherein the semiconductor chip further comprises:
a modulator/demodulator (modem) circuit; and
a memory controller circuit, arranged to control access of the second memory device;
the semiconductor chip is further arranged to store a hardware setting of the modem circuit into the second memory device via the memory controller circuit before the power-off event of the semiconductor chip.

11. An electronic device comprising:
a semiconductor chip, comprising an input/output (I/O) interface circuit; and
a first memory device, external to the semiconductor chip;
wherein the semiconductor chip communicates with the first memory device via the I/O interface circuit; and the semiconductor chip is arranged to fetch at least one hardware setting of the semiconductor chip from the first memory device after a power-on event of the semiconductor chip.

12. The electronic device of claim 11, wherein the first memory device is an internal memory of an integrated circuit (IC) of the electronic device.

13. The electronic device of claim 12, wherein the IC is arranged to leave a power saving mode before the power-on event of the semiconductor chip.

14. The electronic device of claim 12, wherein the I/O interface circuit comprises:
general-purpose input/output (GPIO) hardware; and
a GPIO latch circuit, arranged to latch status of the GPIO hardware;
the IC is arranged to disable the GPIO latch circuit before the power-on event of the semiconductor chip.

15. The electronic device of claim 12, wherein the I/O interface circuit comprises general-purpose input/output (GPIO) hardware;
and the IC is arranged to make the GPIO hardware leave an isolation state before the power-on event of the semiconductor chip.

16. The electronic device of claim 11, further comprising:
a second memory device, external to the semiconductor chip;
wherein the semiconductor chip further comprises:
a memory controller circuit, arranged to control access of the second memory device, wherein the memory controller circuit is further arranged to instruct the second memory device to leave a self-refresh mode after the power-on event of the semiconductor chip.

17. The electronic device of claim 11, further comprising:
a second memory device, external to the semiconductor chip;
wherein the semiconductor chip further comprises:
a memory controller circuit, arranged to control access of the second memory device; and
the IC is further arranged to make the second memory device leaves an isolation state after the power-on event of the semiconductor chip.

18. The electronic device of claim 11, further comprising:
a second memory device, external to the semiconductor chip;
wherein the semiconductor chip further comprises:
a memory controller circuit, arranged to control access of the second memory device according to memory parameters of the second memory device, where said at least one hardware setting comprises the memory parameters of the second memory device.

19. The electronic device of claim 11, wherein said at least one hardware setting comprises general-purpose input/output (GPIO) pinmux parameters of the I/O interface circuit.

20. The electronic device of claim 11, further comprising:
a second memory device, external to the semiconductor chip;
wherein the semiconductor chip further comprises:
a modulator/demodulator (modem) circuit; and
a memory controller circuit, arranged to control access of the second memory device;
the semiconductor chip is further arranged to load a hardware setting of the modem circuit from the second memory device via the memory controller circuit after the power-on event of the semiconductor chip.
